(19) United States
(12) Patent Application Publication
(10) Pub. No.: US 2014/0252613 A1
(43) Pub. Date: Sep. 11, 2014

(54) SEMICONDUCTOR DEVICE

(71) Applicants: Yoshinori IWAMOTO, Tokyo (JP); Kouji SATO, Tokyo (JP); Yutaka NAKAJIMA, Tokyo (JP); Ken HAYAKAWA, Tokyo (JP)

(72) Inventors: Yoshinori IWAMOTO, Tokyo (JP); Kouji SATO, Tokyo (JP); Yutaka NAKAJIMA, Tokyo (JP); Ken HAYAKAWA, Tokyo (JP)

(21) Appl. No.: 14/279,852

(22) Filed: May 16, 2014

Related U.S. Application Data
(62) Division of application No. 12/976,220, filed on Dec. 22, 2010.

(30) Foreign Application Priority Data
Oct. 12, 2010 (JP) 2010-229615
Dec. 16, 2010 (JP) 2010-280391

(51) Int. Cl. H01L 25/065; H01L 23/00

(52) U.S. Cl. CPC H01L 25/0657; H01L 24/14; H01L 24/49
USPC 257/738

(57) ABSTRACT

The present invention reduces the occurrence of fracture in external terminal connecting sections and improves the reliability of secondary packaging of a semiconductor device. Specifically, the present invention provides a semiconductor device including a wiring board, a semiconductor chip mounted on one surface of the wiring board via a bonding member, and external electrodes formed on the other surface of the wiring board and electrically connected to the semiconductor chip. In the semiconductor device, a peripheral end of the bonding member is arranged in a position where the peripheral end does not overlap the external electrodes.

### CROSS-REFERENCE TO RELATED PATENT APPLICATIONS

Japan Priority Application 2010-229615, filed Oct. 12, 2010 including the specification, drawings, claims and abstract, is incorporated herein by reference in its entirety. Japan Priority Application 2010-280391, filed Dec. 16, 2010 including the specification, drawings, claims and abstract, is incorporated herein by reference in its entirety. This application is a Divisional of U.S. application Ser. No. 12/976,220, filed Dec. 22, 2010, incorporated herein by reference in its entirety.

### BACKGROUND OF THE INVENTION

1. Field of the Invention

The present invention relates to a semiconductor device in which a semiconductor chip is mounted on one surface of a wiring board and plural external terminals are arranged in a grid shape on the other surface of the wiring board.

2. Description of Related Art

JP 2001-044324A and JP 2001-044229A disclose a semiconductor device in which a semiconductor chip is mounted on one surface of a wiring board via a bonding member and solder balls electrically connected to the semiconductor chip are disposed on the other surface of the wiring board. The semiconductor device of this type is called a BGA (Ball Grid Array) type semiconductor device.

In the related arts explained above, the semiconductor chip is mounted on the wiring board via the bonding member having a size equivalent to the size of the semiconductor chip. In some cases, an end of the bonding member overlaps the solder balls arranged on the other surface of the wiring board. In these cases, since two kinds of distortion are applied to the solder balls, connecting sections between the wiring board and the solder balls of the semiconductor device (hereinafter referred to as solder ball connecting sections) are broken. As a result, reliability in packaging the semiconductor device on a printed board (hereinafter referred to as secondary packaging) falls.

The two kinds of distortion applied to the solder balls are caused by shearing force applied to the solder balls because of expansion and contraction of the semiconductor device due to a temperature change and a warp that occurs in a boundary area because of a difference in the modulus of elasticity between an applied area of the bonding member and an area without the bonding member.

### SUMMARY OF THE INVENTION

In one embodiment, a semiconductor device according to the present invention includes: a wiring board, a semiconductor chip mounted on one surface of the wiring board via a bonding member; and external electrodes formed on the other surface of the wiring board and electrically connected to the semiconductor chip. A peripheral end of the bonding member is arranged in a position where the peripheral end does not overlap the external electrodes.

Since the semiconductor device is configured as explained above, it is possible to prevent a warp that occurs in a boundary area because of the difference in the modulus of elasticity between an applied area of the bonding member and an area without the bonding member from occurring in an area where the bonding member overlaps external terminals such as solder balls. Consequently, distortion applied to the external terminals in secondary packaging is dispersed. This makes it possible to reduce occurrence of fracture in external terminal connecting sections and improve reliability of the secondary packaging of the semiconductor device.

Since the peripheral end of the bonding member is arranged to extend outward from a peripheral end of the semiconductor chip, the peripheral end of the semiconductor chip and the peripheral end of the bonding member are arranged in different positions. Therefore, distortion of the semiconductor chip and distortion of the bonding member are dispersed without being concentrated on one point. As a result, it is possible to further reduce the distortion applied to the external terminals.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plan view showing a schematic configuration of a semiconductor device according to a first exemplary embodiment;

FIG. 2 is a sectional view showing the schematic configuration of the semiconductor device according to the first exemplary embodiment;

FIG. 3 is a sectional view showing an assembly flow of the semiconductor device according to the first exemplary embodiment;

FIG. 4 is a sectional view showing the assembly flow of the semiconductor device according to the first exemplary embodiment;

FIG. 5 is a plan view showing a schematic configuration of a semiconductor device according to a second exemplary embodiment;

FIG. 6 is a sectional view showing the schematic configuration of the semiconductor device according to the second exemplary embodiment;

FIG. 7 is a sectional view showing an assembly flow of the semiconductor device according to the second exemplary embodiment;

FIG. 8 is a sectional view showing the assembly flow of the semiconductor device according to the second exemplary embodiment;

FIG. 9 is a plan view showing a schematic configuration of a semiconductor device according to a third exemplary embodiment;

FIG. 10 is a sectional view showing the schematic configuration of the semiconductor device according to the third exemplary embodiment;

FIG. 11 is a plan view showing a schematic configuration of a semiconductor device according to a fourth exemplary embodiment;

FIG. 12 is a sectional view (a) corresponding to a corner part of a semiconductor device according to a fourth exemplary embodiment, and is a sectional view (b) showing the part except the corner part; and

FIG. 13 is a sectional view showing a schematic configuration of a semiconductor device according to another exemplary embodiment.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

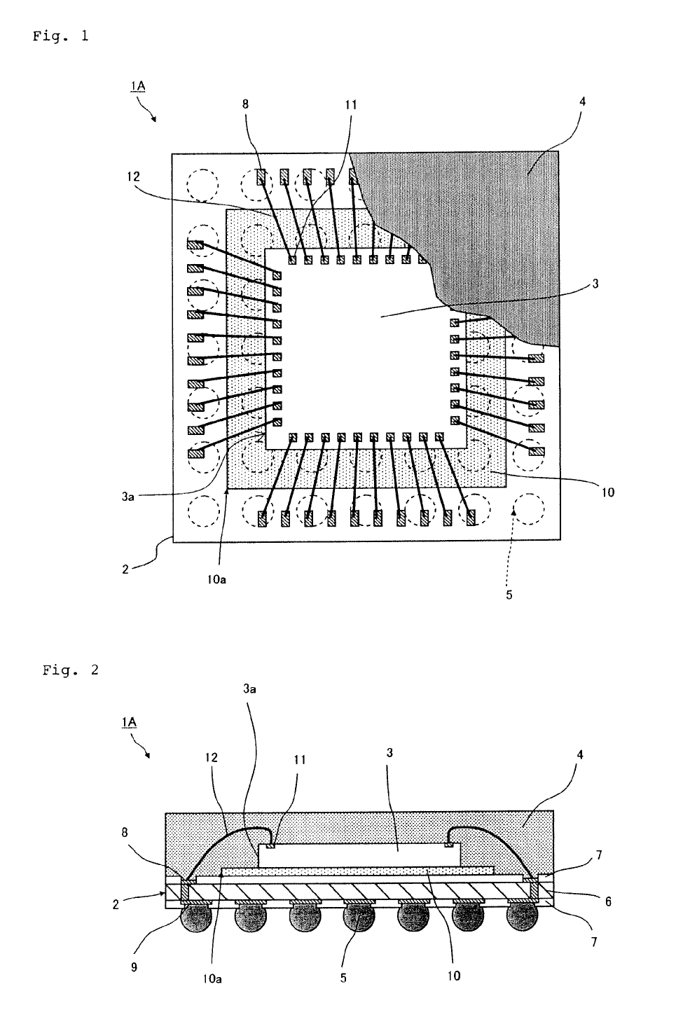

FIG. 1 is a plan view showing a schematic configuration of a semiconductor device according to a first exemplary embodiment. FIG. 2 is a sectional view of the schematic configuration.

Semiconductor device 1A according to this exemplary embodiment shown in FIGS. 1 and 2 includes wiring board 2 on one surface of which a predetermined wiring pattern (not shown) is formed, semiconductor chip 3 mounted on one surface of wiring board 2, sealing member 4 that covers the periphery of semiconductor chip 3 and that seals an electric connection section between semiconductor chip 3 and wiring board 2, and metal balls such as solder balls 5, which are external terminals, disposed on the other surface of wiring board 2. In FIG. 1, sealing member 4 is partially removed to clearly show the structure.

Wiring hoard 2 is formed by dividing, for each of plural product forming sections, a substantially rectangular glass epoxy wiring board (hereinafter referred to as wiring motherboard) including the plural product forming sections divided in a matrix shape in a board surface and singulating the wiring motherboard. Predetermined wiring patterns (not shown) are formed on one surface and the other surface of insulating base material 6 of wiring board 2. Wires of the wiring patterns are partially covered with insulating film (e.g., solder resist) 7.

Plural connection pads 8 are formed in a section not covered with insulating film 7 such as the solder resist in the wires formed on one surface of wiring board 2. Plural lands 9 are formed in a section not covered with insulating film 7 such as the solder resist in the wires formed on the other surface of wiring board 2. Connection pads 8 and lands 9 corresponding to connection pads 8 are electrically connected via wires formed on the inside of wiring board 2.

Semiconductor chip 3 is mounted on insulating film 7 on the one surface side of wiring board 2 via bonding member 10. A surface (a rear surface) on the opposite side of one surface (a front surface), on which a circuit including electrode pads 11 is formed, of semiconductor chip 3 is bonded to bonding member 10. Electrode pads 11 and connection pads 8 corresponding to electrode pads 11 are electrically connected by conductive wires 12.

As bonding member 10, for example, insulative paste or a DAF (Die Attached Film) is used. Bonding member 10 is provided such that peripheral end 10a thereof is arranged in a position where peripheral end 10a does not overlap solder balls 5 on the other surface side of wiring board 2, for example, a position between solder balls 5 arranged in a grid shape. Bonding member 10 is formed in size larger than the rear surface size of semiconductor chip 3. Bonding member 10 is arranged such that peripheral end 10a of bonding member 10 extends from peripheral end 3a of semiconductor chip 3.

In this way, this application provides semiconductor device 1A in which peripheral end 10a of bonding member 10 is arranged in the position where peripheral end 10a does not overlap solder balls 5, for example, the position between solder balls 5. With this configuration, it is possible to prevent a warp that occurs in a boundary area because of a difference in the modulus of elasticity between an area where bonding member 10 is applied and an area without bonding member 10 from occurring in an area where peripheral end 10a overlaps solder balls 5. At the same time, shearing force applied to solder balls 5 because of expansion and contraction of semiconductor device 1A due to a temperature change is also suppressed. Therefore, it is possible to disperse distortion applied to solder balls 5 in secondary packaging. It is possible to reduce the occurrence of fracture in solder ball connecting sections and to improve reliability of the secondary packaging of semiconductor device 1A.

This application also provides semiconductor device 1A in which peripheral end 10a of bonding member 10 is arranged to extend sideways from peripheral end 3a of semiconductor chip 3. In such a configuration, since peripheral end 3a of semiconductor chip 3 and peripheral end 10a of bonding member 10 are arranged in different positions, distortion at peripheral end 3a of semiconductor chip 3 and distortion at peripheral end 10a of bonding member 10 are dispersed without being concentrated on one point. Therefore, it is possible to further reduce distortion applied to solder balls 5 in the secondary packaging.

A manufacturing process for semiconductor device 1A is explained below.

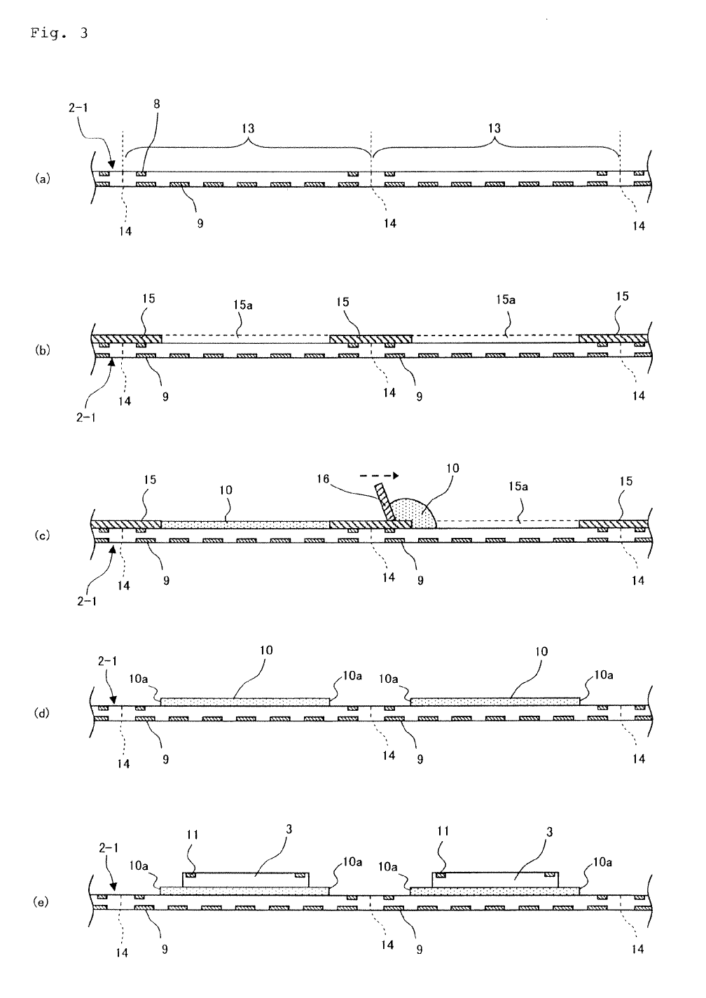

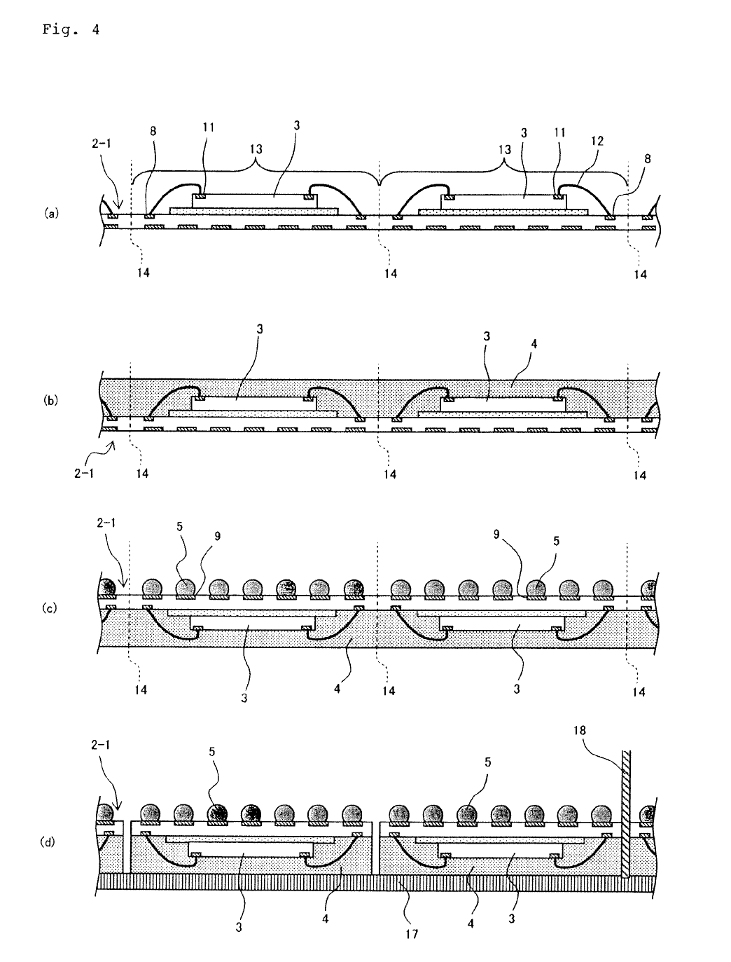

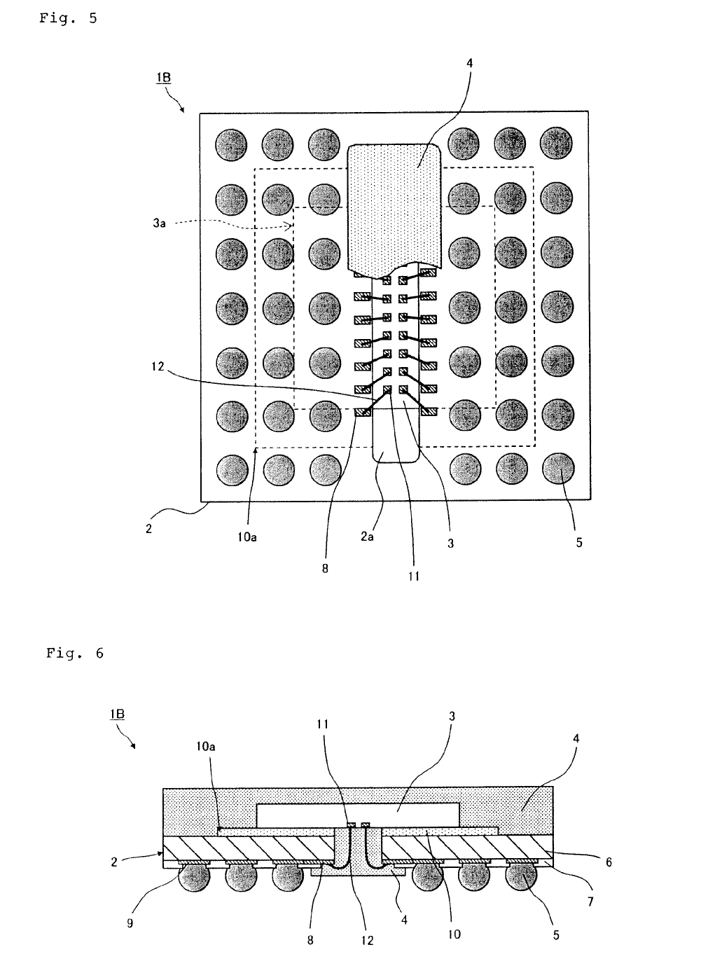

FIGS. 3 and 4 are sectional views showing an assembly flow of the semiconductor device according to the first exemplary embodiment.

First, wiring motherboard 2-1 shown in FIG. 3(a) is prepared. Wiring motherboard 2-1 includes plural product forming sections 13 (sections changing to wiring boards 2 after being cut) divided in a matrix shape in a board surface. Dicing lines 14 for dividing wiring motherboard 2-1 for each of product forming sections 13 are provided in boundaries among respective product forming sections 13.

Subsequently, a disposing step for chip bonding member 10 is carried out. Specifically, as shown in FIG. 3(b), mask for printing 15 is set on one surface of wiring motherboard 2-1. Mask for printing 15 includes plural opening holes 15a respectively corresponding to product forming sections 13. Respective opening holes 15a are formed such that the opening edges thereof are arranged in areas among lands 9 for solder ball mounting. Lands 9 are arranged in a grid shape for each of rectangular product forming sections 13 on the other surface side of wiring motherboard 2-1.

As shown in FIG. 3(c), bonding member 10 (e.g., insulative paste) applied on mask for printing 15 is supplied into opening holes 15a by squeezee 16. Thereafter, mask for printing 15 is removed. Consequently, as shown in FIG. 3(d), layers of bonding members 10 having predetermined thickness can be formed on one of the surfaces of respective product forming sections 13, and peripheral ends 10a of bonding members 10 can be arranged in positions corresponding to spaces among lands 9. As bonding members 10, a DAF (Die Attached Film) may be used instead of the insulative paste.

Subsequently, a die bonding step is carried out. Specifically, as shown in FIG. 3(e), semiconductor chips 3 are mounted on one of the surfaces of respective product forming sections 13 of wiring motherboard 2-1. The layers of bonding members 10 are formed in size larger than the size occupied by semiconductor chips 3 on the board. Consequently, peripheral ends 10a of bonding members 10 are arranged to extend from respective sides of semiconductor chips 3. When bonding members 10 are the DAF, a DAF, which is larger than the size occupied by semiconductor chips 3 in this way and peripheral ends 10a of which can be arranged in the positions corresponding to the spaces among lands 9 when bonded on the board, is used.

Semiconductor chips 3 include Si substrates on one of the surfaces of which logic circuits, memory circuits, or the like are formed. Plural electrode pads 11 are formed in positions near the peripheral edges of the Si substrates. Passivation films (not shown) that protect circuit forming surfaces are formed on one of the surfaces of semiconductor chips 3 excluding electrode pads 11. In the first exemplary embodiment, the rear surface sides (surfaces opposed to the circuit forming surfaces) of semiconductor chips 3 are bonded and fixed to one surface of wiring motherboard 2-1 via the layers of bonding members 10.

When semiconductor chips 3 are finished to be mounted on all product forming sections 13, the manufacturing process shifts to a wire bonding step. As shown in FIG. 4(a), in the wire bonding step, electrode pads 11 formed on one of the surfaces of semiconductor chips 3 and connection pads 8 on wiring motherboard 2-1 corresponding to electrode pads 11 are connected via conductive wires 12. Such wires 12 are made of, for example, Au or Cu. A not-shown wire bonding apparatus is used for wire bonding. Specifically, after one of the ends of wires 12 that are fused and that have balls formed thereon are ultrasonic thermo-compression bonded to electrode pads 11 of semiconductor chips 3, the other ends of wires 12 are ultrasonic thermo-compression bonded to corresponding connection pads 8 on wiring motherboard 2-1. Wires 12 are formed to draw a predetermined loop shape to avoid interference with corners on end sides of semiconductor chips 3.

Subsequently, wiring motherboard 2-1 is shifted to a sealing step. In the sealing step, as shown in FIG. 4(b), sealing member 4 that collectively covers plural product forming areas 13 on the surface side on which semiconductor chips 3 are mounted is formed. Specifically, the sealing step is executed by using a molding apparatus such as a transfer mold apparatus that includes a molding die (not shown) including an upper die and a lower die. A cavity having the appropriate size for collectively covering plural product forming sections 13 is formed in the upper die. A recess for arranging wiring motherboard 2-1 is formed in the lower die. Wiring motherboard 2-1, for which the wire bonding step is completed, is set in the recess of the lower die. The peripheral edge of wiring motherboard 2-1 is clamped by the upper die and the lower die, whereby a cavity having the size described above is formed in an upper part of wiring motherboard 2-1. Thereafter, thermosetting sealing resin (e.g., epoxy resin) is filled in the cavity and cured at a predetermined temperature (e.g., 180° C.), whereby the sealing resin is hardened and sealing member 4 is formed.

Subsequently, wiring motherboard 2-1 is shifted to a ball mount step. Specifically, as shown in FIG. 4(c), conductive solder balls 5 are joined on plural lands 9 arranged in a grid shape for each of product forming sections 13 on the other surface of wiring motherboard 2-1. In the ball mount step, a not-shown ball mounter having plural absorbing holes formed therein to correspond to the arrangement of lands 9 on wiring motherboard 2-1 is used. Specifically, solder balls 5 are held in the absorbing holes and collectively joined to plural lands 9 via fluxes.

Thereafter, wiring motherboard 2-1 is shifted to a dicing step. Specifically, as shown in FIG. 4(d), dicing tape 17 is bonded on sealing member 4 side of wiring motherboard 2-1. Wiring motherboard 2-1 is cut along dicing lines 14 lengthwise and crosswise by dicing blade 18 of a dicing apparatus, whereby product forming sections 13 are separated from one another. Thereafter, product forming sections 13 are picked up from dicing tape 17, whereby semiconductor device 1A shown in FIGS. 1 and 2 are obtained.

### Second Exemplary Embodiment

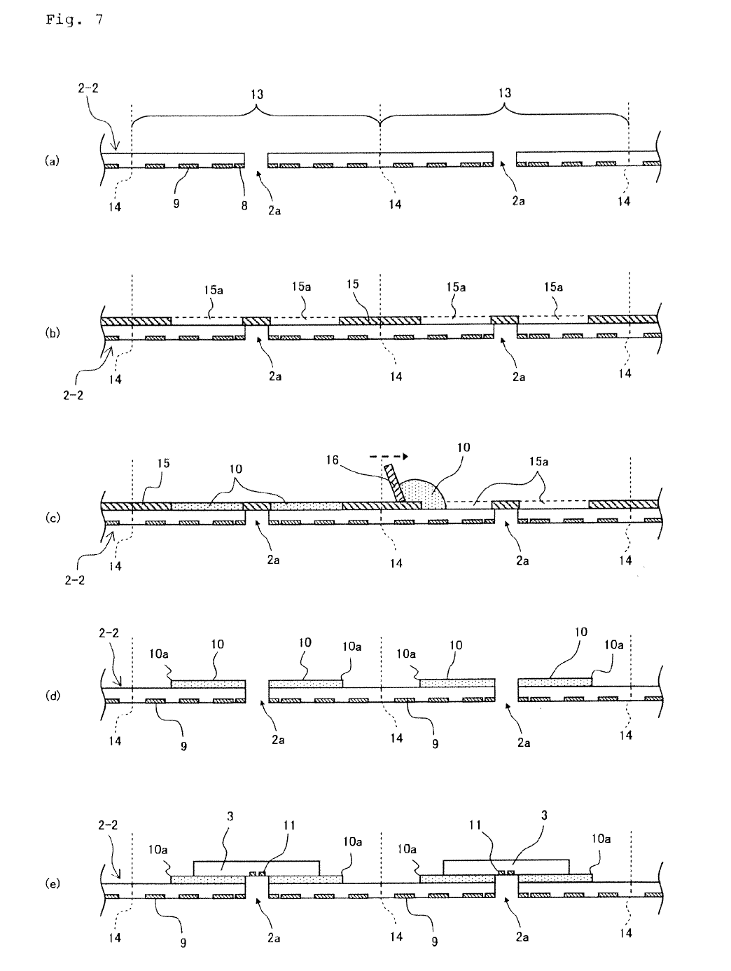

A second exemplary embodiment is explained below. Components that are the same as those in the first exemplary embodiment are denoted by the same reference numerals and signs. FIG. 5 is a plan view showing a schematic configuration of a semiconductor device according to the second exemplary embodiment. FIG. 6 is a sectional view of the schematic configuration.

Semiconductor device 1B according to this exemplary embodiment shown in FIGS. 5 and 6 includes wiring board 2 having opening 2a formed in the center, semiconductor chip 3 mounted on one surface of wiring board 2, sealing member 4 that covers the periphery of semiconductor chip 3 and that seals an electric connection section of semiconductor chip 3 and wiring board 2 in opening 2a, and metal balls of solder balls 5, which are external terminals, disposed on the other surface of wiring board 2. In FIG. 5, sealing member 4 is partially removed to clearly show the structure.

Wiring board 2 is formed by dividing, for each of the plural product forming sections, a substantially rectangular glass epoxy wiring board (hereinafter referred to as wiring motherboard) that includes the plural product forming sections divided in a matrix shape in a board surface and singulating the wiring motherboard. Slender rectangular opening 2a piercing through both the surfaces of wiring board 2 is formed in the center area of wiring board 2 corresponding to each of the product forming sections. Predetermined wiring patterns (not shown) are formed on the other surface of insulating base material 6 of wiring board 2 excluding opening 2a. Wires of the wiring patterns are partially covered with insulating film (e.g., solder resist) 7.

Plural connection pads 8 and lands 9 are formed in a section not covered with insulating film 7 such as the solder resist in the wires formed on the other surface of wiring board 2. The wires in a section covered with insulating film 7 include wires that electrically connect connection pads 8 and lands 9 corresponding to connection pads 8.

Semiconductor chip 3 is mounted on one surface of wiring board 2 via bonding member 10. A surface (a front surface), on which a circuit including electrode pads 11 is formed, of semiconductor chip 3 is bonded to bonding member 10. Plural electrode pads 11 are linearly arranged in a center area of semiconductor chip 3 and exposed from opening 2a of wiring board 2. Plural connection pads 8 are arranged along edges of two long sides of opening 2a on the other surface of wiring board 2. Electrode pads 11 and connection pads 8 corresponding to electrode pads 11 are electrically connected by conductive wires 12. Consequently, electrode pads 11 of semiconductor chip 3 and lands 9 corresponding to electrode pads 11 are electrically connected.

Wiring board 2 includes two areas divided by slender rectangular opening 2a, i.e., two areas from two long sides of rectangular opening 2a to respective end sides of wiring board 2 opposed to the respective long sides. Plural lands 9 are arranged in a grid shape on the other surface side (a surface on the opposite side of semiconductor chip 3) of wiring board 2 of each of the areas. Solder balls 5 are joined to respective lands 9.

As bonding members 10 on the one surface side of wiring board 2, for example, insulative paste or a DAF (Die Attached Film) is used. Bonding members 10 in this exemplary embodiment are arranged in the respective areas divided by opening 2a. Each of bonding members 10 spreads from one long side of rectangular opening 2a to the end side of wiring board 2 opposed to the long side. Each of bonding members 10 is provided such that peripheral end 10a on the opposite side of opening 2a side is arranged in a position where peripheral ends 10a does not overlap solder balls 5 on the other surface side of wiring board 2, for example, a position between solder balls 5 arranged in a grid shape. Bonding members 10 are formed in a size that is larger than the rear surface size of semiconductor chip 3. Consequently, peripheral ends 10a of bonding members 10 are arranged to extend from peripheral end 3a of semiconductor chip 3.

Effects realized by arranging peripheral ends 10a of bonding members 10 in such positions are the same as the effects explained in the first exemplary embodiment. Further, in this exemplary embodiment, since a face down system for bonding the circuit forming surface side of semiconductor chip 3 to one surface of wiring hoard 2 is adopted, it is possible to reduce the thickness of sealing member 4 on one surface side of wiring board 2. Therefore, it is possible to realize a reduction in thickness of the semiconductor device. Since connection pads 8 and lands 9 are formed on the other surface side of wiring board 2, it is possible to use a wiring board including only one wiring layer.

A manufacturing process for semiconductor device 1B is explained below.

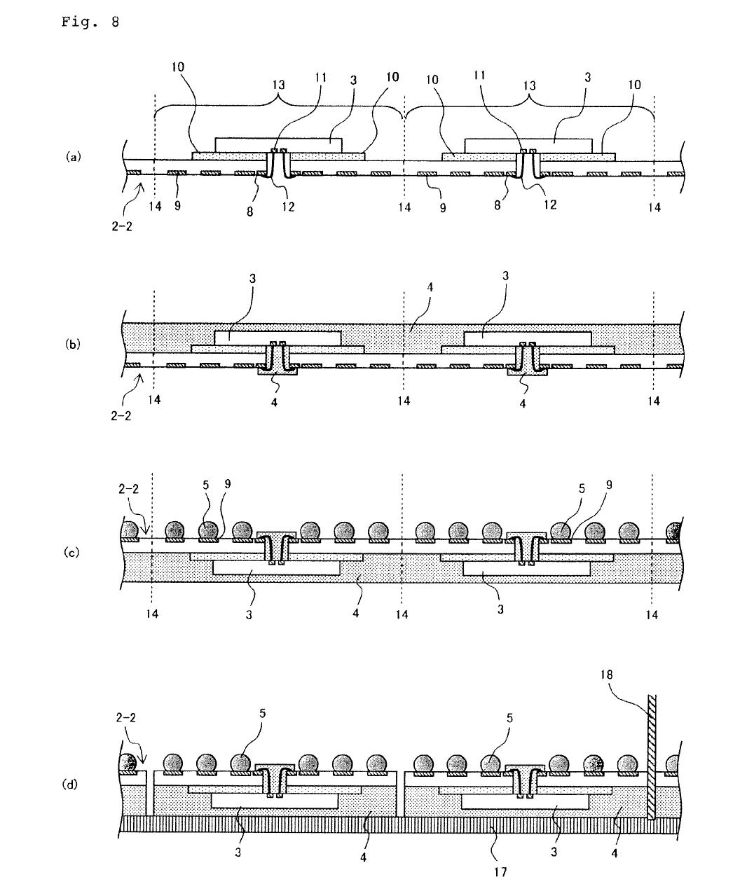

FIGS. 7 and 8 are sectional views showing an assembly flow of the semiconductor device according to the second exemplary embodiment.

First, wiring motherboard 2-2 shown in FIG. 7(a) is prepared. Wiring motherboard 2-2 includes plural product forming sections 13 (sections changing to wiring boards 2 after being cut) divided in a matrix shape in a board surface. Dicing lines 14 for dividing wiring motherboard 2-2 for each of product forming sections 13 are provided in boundaries among respective product forming sections 13. Slender rectangular openings 2a are formed in the centers of product forming sections 13.

Subsequently, a disposing step for chip bonding member 10 is carried out. Specifically, as shown in FIG. 7(b), a mask for printing 15 is set on one surface of wiring motherboard 2-2. The mask for printing 15 includes plural opening holes 15a respectively corresponding to product forming sections 13. Respective opening holes 15a are formed such that opening edges thereof are arranged in areas among lands 9 for solder ball mounting. Lands 9 are arranged in a grid shape in areas on both sides of openings 2a in each of product forming sections 13 on the other surface side of wiring motherboard 2-2.

As shown in FIG. 7(c), bonding member 10 (e.g., insulative paste) applied on the mask for printing 15 is supplied into opening holes 15a by squeezee 16. Thereafter, the mask for printing 15 is removed. Consequently, as shown in FIG. 7(d), layers of bonding members 10 having a predetermined thickness can be formed on one of the surfaces of respective product forming sections 13 and peripheral ends 10a on the opposite sides of the opening 2a sides of bonding members 10 can be arranged in positions corresponding to spaces among lands 9. As bonding members 10, a DAF (Die Attached Film) may be used instead of the insulative paste.

Subsequently, a die bonding step is carried out. Specifically, as shown in FIG. 7(e), semiconductor chips 3 are mounted on one of the surfaces of respective product forming sections 13 of wiring motherboard 2-2. The layers of bonding members 10 are formed in a size larger than the size occupied by semiconductor chips 3 on the board. Consequently, peripheral ends 10a on the opposite sides of opening 2a sides of bonding members 10 are arranged to extend from respective sides of semiconductor chips 3. When bonding members 10 are the DAF, a DAF, which is larger than the size occupied by semiconductor chips 3 in this way and peripheral ends 10a of which can be arranged in the positions corresponding to the spaces among lands 9 when bonded on the board, is used.

In the second exemplary embodiment, the circuit forming surfaces (surfaces on which electrode pads 11 are formed) of semiconductor chips 3 are faced down. The circuit forming surfaces are bonded and fixed to one surface of wiring motherboard 2-2 via the layers of bonding members 10. At this point, semiconductor chips 3 are fixed such that electrode pads 11 are exposed from openings 2a of product forming sections 13 of wiring motherboard 2-2.

When semiconductor chips 3 are finished to be mounted on all product forming sections 13, the manufacturing process shifts to a wire bonding step. As shown in FIG. 8(a), in the wire bonding step, electrode pads 11 formed on one of the surfaces of semiconductor chips 3 and connection pads 8 in positions near the peripheral edges of openings 2a on wiring motherboard 2-2 corresponding to electrode pads 11 are connected via conductive wires 12. Such wires 12 are made of, for example, Au or Cu. A not-shown wire bonding apparatus is used for wire bonding. Wires 12 are formed to draw a predetermined loop shape to avoid interference with corners of peripheral edges of openings 2a.

Subsequently, wiring motherboard 2-2 is shifted to a sealing step. In the sealing step, as shown in FIG. 8(b), sealing member 4 that collectively covers plural product forming areas 13 on the surface side on which semiconductor chips 3 are mounted is formed. The sealing step is executed by using a molding apparatus such as a transfer mold apparatus that includes a molding die (not shown) including an upper die and a lower die. A recess for setting wiring motherboard 2-2 is formed in the lower die. In this exemplary embodiment, a groove through which thermosetting sealing resin (e.g., epoxy resin) can be injected into openings 2a of product forming sections 13 is formed on a substrate supporting surface of the recess.

Subsequently, wiring motherboard 2-2 is shifted to a ball mount step. Specifically, as shown in FIG. 8(c), conductive solder balls 5 are joined on plural lands 9 arranged in a grid shape for each of product forming sections 13 on the other surface of wiring motherboard 2-2. In the ball mount step, a not-shown ball mounter having plural absorbing holes formed therein to correspond to the arrangement of lands 9 on wiring motherboard 2-2 is used. Solder balls 5 are collectively joined to plural lands 9.

Thereafter, wiring motherboard 2-2 is shifted to a dicing step. Specifically, as shown in FIG. 8(d), dicing tape 17 is bonded on sealing member 4 side of wiring motherboard 2-2. Wiring motherboard 2-2 is cut along dicing lines 14 lengthwise and crosswise by dicing blade 18 of a dicing apparatus, whereby product forming sections 13 are separated from one another. Thereafter, product forming sections 13 are picked up from dicing tape 17, whereby semiconductor device 1B shown in FIGS. 5 and 6 are obtained.

### Third Exemplary Embodiment

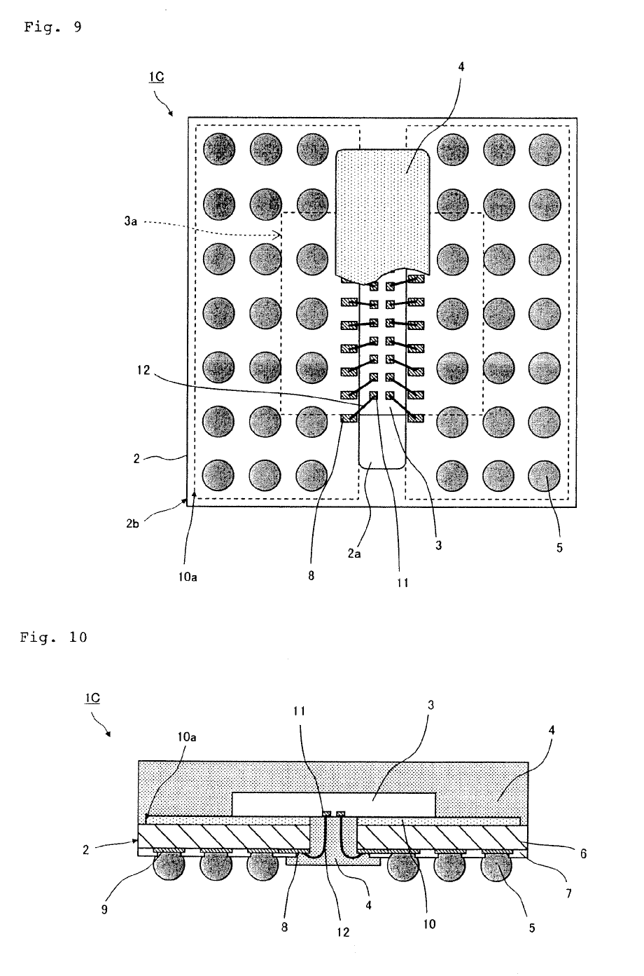

A third exemplary embodiment is explained below. Components that are the same as those in the first exemplary embodiment are denoted by the same reference numerals and signs. FIG. 9 is a plan view showing a schematic configuration of a semiconductor device according to the third exemplary embodiment. FIG. 10 is a sectional view of the schematic configuration.

Semiconductor device 1C according to this exemplary embodiment shown in FIGS. 9 and 10 is configured substantially the same as semiconductor device 1B according to the second exemplary embodiment. However, semiconductor device 1C is different from semiconductor device 1B in that bonding members 10 are formed over substantially the entire surface on the one surface side of wiring board 2. Specifically, peripheral ends 10a of bonding members 10 spread from the edges of opening 2a to the vicinities of outer peripheral end 2b of wiring board 2. Consequently, peripheral ends 10a of bonding members 10 are arranged on the outer sides of external terminal groups including plural solder balls 5 arranged in a grid shape. In this way, in the third exemplary embodiment, since peripheral ends 10a of bonding members 10 are arranged in positions where peripheral ends 10a do not overlap solder balls 5, effects that are the same as those in the first and second exemplary embodiments are obtained. Specifically, it is possible to reduce distortion applied to solder balls 5 in the secondary packaging.

In the third exemplary embodiment, since bonding members 10 are formed over substantially the entire surface of one surface of wiring board 2, it is possible to space peripheral ends 10a of bonding members 10 further away from peripheral end 3a of semiconductor chip 3 than in the second exemplary embodiment. As a result, it is possible to further reduce interference between distortion at peripheral end 3a of semiconductor chip 3 and distortion at peripheral ends 10a of bonding members 10 than in the second exemplary embodiment.

Bonding members 10 may be configured such that peripheral ends 10a of bonding members 10 and outer peripheral end 2b of wiring board 2 coincide with each other. However, as in this exemplary embodiment, since peripheral ends 10a of bonding members 10 are arranged slightly on the inner side from peripheral end 2b of wiring board 2, it is possible to prevent moisture from being absorbed from the outside of semiconductor device 1C through bonding members 10.

A manufacturing process for the semiconductor device 1C according to this exemplary embodiment is the same as the manufacturing process for semiconductor device 1B according to the second exemplary embodiment. Therefore, explanation of the manufacturing process is omitted.

### Fourth Exemplary Embodiment

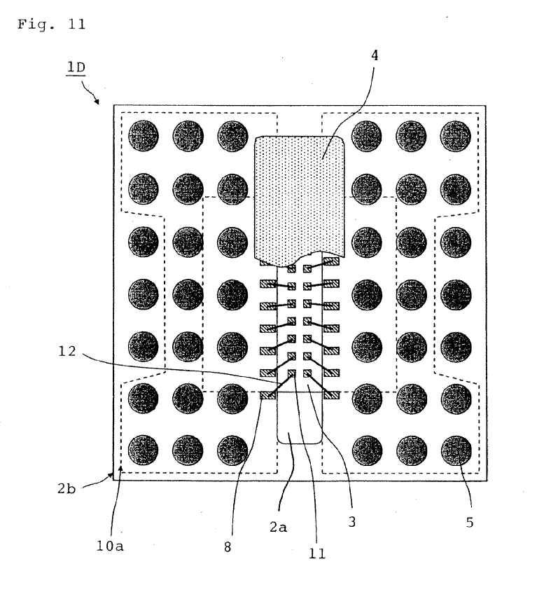

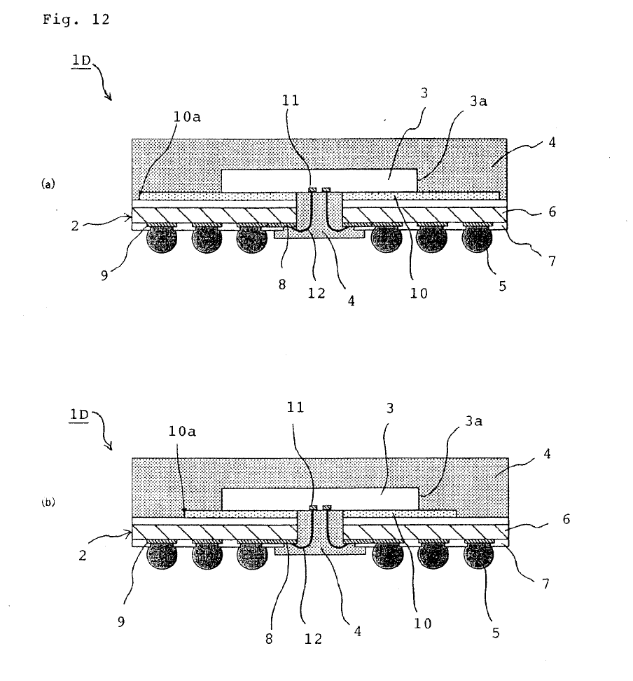

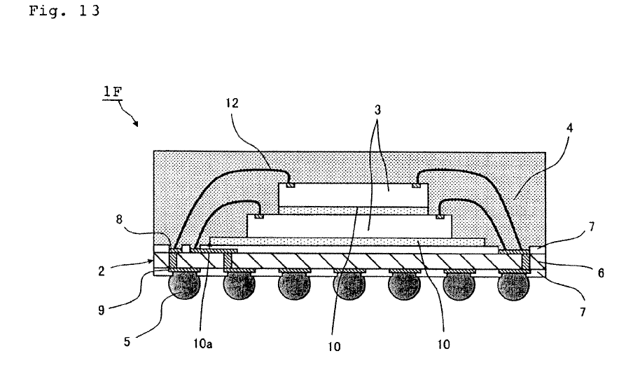

A fourth exemplary embodiment is explained below. Components that are the same as those in the first exemplary embodiment are denoted by the same reference numerals and signs. FIG. 11 is a plan view showing a schematic configuration of a semiconductor device according to the fourth exemplary embodiment. FIG. 12(a) is a sectional view corresponding to a corner part of a semiconductor device according to a fourth exemplary embodiment. FIG. 12(b) is a sectional view showing the part except the corner part.

Semiconductor device 1D according to this exemplary embodiment shown in FIGS. 11 and 12 is configured substantially the same as semiconductor device 1B according to the second exemplary embodiment. However, semiconductor device 1D is different from semiconductor device 1B in that parts of peripheral ends 10a of bonding members 10 correspond to four corners of a rectangular region where a group of solder balls 5 is arranged in a grid shape and the parts of peripheral ends 10a are arranged on the vicinities of outer peripheral end 2b of wiring board 2.

In the fourth exemplary embodiment, also, peripheral ends 10a of bonding members 10 are arranged to extend outward from peripheral end 3a of semiconductor chip 3 and are arranged in positions where peripheral ends 10a do not overlap solder balls 5, and therefore effects that are the same as those in the first and second exemplary embodiments are obtained.

In this embodiment, specifically, peripheral end parts of bonding members 10 corresponding to four corners of a rectangular region of the solder balls group are arranged to extend outward from the region of the solder balls group to the vicinities of outer peripheral end 2b of wiring board 2. Consequently, it is possible to heighten durability of temperature cycle test at four corners the region where the group of solder balls 5 is arranged in a grid shape. Furthermore, the parts except peripheral end parts of bonding members 10 corresponding to the above four corners are arranged inside the region of the solder balls group and are arranged in positions where peripheral ends 10a do not overlap solder balls 5, such as positions between solder balls 5. With this arrangement, it is possible prevent moisture from being absorbed from outer peripheral end 2b of wiring board 2 through bonding members 10.

A manufacturing process for the semiconductor device 1D according to this exemplary embodiment is the same as the manufacturing process for semiconductor device 1B according to the second exemplary embodiment. Therefore, explanation of the manufacturing process is omitted.

While exemplary embodiments of the present invention have been described with reference to the drawings, the present invention is not limited to the illustrated structure and form; the present invention can be implemented by suitably changing or combining the above-described exemplary embodiments without departing from the technical spirit of the present invention. For example, in the exemplary embodiments, the semiconductor device in which one semiconductor chip is mounted on one wiring board is explained. However, the present invention is not limited to this. Semiconductor device 1F in which plural semiconductor chips 3 are stacked on one wiring board 2 is also included in the invention as claimed in the current application as long as peripheral end 10a of bonding member 10 for bonding semiconductor chip 3, which is closest to wiring board 2 as shown in FIG. 13, onto wiring board 2, is arranged in a position where peripheral end 10a does not overlap solder balls.

Although the inventions has been described above in connection with several preferred embodiments thereof, it will be appreciated by those skilled in the art that those embodiments are provided solely for illustrating the invention, and should not be relied upon to construe the appended claims in a limiting sense.

What is claimed is:

1. A semiconductor device comprising:
a wiring board defined by first and second edges opposite to each other and by third and fourth edges opposite to each other;
a first semiconductor chip mounted on one surface of the wiring board via a bonding member;
a second semiconductor chip mounted on an other surface of the first semiconductor chip; and
external electrodes formed on an other surface of the wiring board and electrically connected to the first and the second semiconductor chips, the external electrodes comprising a plurality of first external electrodes arranged along the first, second, third and fourth edges so as to define a first rectangular shape and a plurality of second external electrodes arranged along the first, second, third and fourth edges so as to define a second rectangular shape that is smaller than the first rectangular shape, the second external electrodes being arranged inside the first rectangular shape,
wherein the bonding member includes four peripheral ends defining a third rectangular shape, each of the four peripheral ends is substantially in parallel to the first, second, third and fourth edges of the wiring board, respectively, and
wherein each of the four peripheral ends of the bonding member is protruded from a corresponding edge of the first semiconductor chip, and the four peripheral ends of the bonding member are arranged so that the third rectangular shape is positioned between the first rectangular shape and the second rectangular shape in plane view without overlapping the first and second external electrodes.

2. The semiconductor device according to claim 1, wherein the external electrodes are conductive balls and are disposed in a grid shape on the other surface of the wiring board.

3. The semiconductor device according to claim 1, further comprising:
electrode pads formed on surfaces of the first and second semiconductor chips; and connection pads formed in positions adjacent a peripheral edge on the other surface of the wiring board and electrically connected to the electrode pads of first and second semiconductor chips, wherein the connection pads and the external electrodes are made conductive to each other via wires formed on the other surface of the wiring board.

4. The semiconductor device according to claim 1, wherein the bonding member is made of conductive paste.

5. The semiconductor device according to claim 1, further comprising a sealing member that is formed on one surface of the wiring board and that seals a periphery of the first and second semiconductor chips.

6. The semiconductor device according to claim 1, wherein the external electrodes include an outermost external electrode and an adjacent external electrode is disposed adjacent to the outermost external electrode toward a center of the wiring substrate, and the peripheral end of the bonding member is arranged between the outermost external electrode and the adjacent external electrode in plane view.

7. The semiconductor device according to claim 6, wherein the outermost external electrode is arranged outside the first semiconductor chip in plane view.

8. The semiconductor device according to claim 1, wherein the wiring board includes a plurality of lands formed on the other surface, and
the external electrodes are formed on the lands of the wiring substrate and are electrically connected to the first and second semiconductor chips via the lands and the connection pads.

9. The semiconductor device according to claim 1, wherein a line between the adjacent two of the external electrodes is substantially perpendicular to the peripheral end of the bonding member.

10. The semiconductor device according to claim 1, wherein the bonding member is a die attached film.

11. The semiconductor device according to claim 1, wherein the peripheral end of the bonding member is substantially perpendicular to the wiring board, and
a thickness of the peripheral end of the bonding member is substantially equal to a thickness of a remaining part of the bonding member.

12. The semiconductor device according to claim 1, wherein the peripheral end of the bonding member is protruded from a corresponding edge of the first semiconductor chip and is arranged between adjacent two of the external electrodes in plane view without overlapping the external electrodes.

13. The semiconductor device according to claim 1, wherein the second semiconductor chip has an area in plane view less than that of the first conductor chip.

14. The semiconductor device according to claim 1, further comprising:
another bonding member disposed between the first and second semiconductor chips.

15. A semiconductor device comprising:
a wiring board defined by four side edges;
a first semiconductor chip including electrode pads formed on one surface of the first semiconductor chip, and mounted on one surface of the wiring board via a bonding member, an other surface of the first semiconductor chip opposed to the one surface of the first semiconductor chip being bonded to the one surface of the wiring board;
a second semiconductor chip including electrode pads formed on one surface of the second semiconductor chip, and mounted on one surface of the first semiconductor chip;
conductive balls as external electrodes disposed in a grid shape on an other surface of the wiring board and electrically connected to the first and semiconductor chips, the conductive balls comprising first conductive balls arranged along the four side edges so as to define a first rectangular shape and second conductive balls arranged along the four side edges so as to define a second rectangular shape that is smaller than the first rectangular shape, the second conductive balls being arranged inside the first rectangular shape,
wherein the bonding member includes four peripheral ends defining a third rectangular shape, the four peripheral ends are substantially in parallel to the four side edges of the wiring board, respectively, each of the four peripheral ends of the bonding member is protruded from a corresponding edge of the first semiconductor chip, the four peripheral ends of the bonding member are arranged so that the third rectangular shape is positioned between the first rectangular shape and the second rectangular shape in plane view without overlapping the first and second conductive balls, and
each of the second conductive halls is arranged adjacent to a corresponding one of the first conductive balls.

16. The semiconductor device according to claim 15, wherein the peripheral end of the bonding member is arranged between the outermost conductive ball and the adjacent conductive ball in plane view, and the adjacent conductive ball is disposed adjacent to the outermost conductive ball.

17. The semiconductor device according to claim 15, wherein the bonding member is a die attached film.

18. The semiconductor device according to claim 15, wherein the peripheral end of the bonding member is substantially perpendicular to the wiring board, and
a thickness of the peripheral end of the bonding member is substantially equal to a thickness of a remaining part of the bonding member.

19. The semiconductor device according to claim 15, wherein the peripheral end of the bonding member is protruded from a corresponding edge of the first semiconductor chip and is arranged between the outermost conductive ball and a corresponding peripheral end of the first semiconductor chip in plane view without overlapping the conductive balls.

20. The semiconductor device according to claim 15, wherein the second semiconductor chip has an area in plane view less than that of the first second conductor chip.
